(19) United States
(12) Patent Application Publication
(10) Pub. No.: US 2025/0287565 A1
(43) Pub. Date: Sep. 11, 2025

(54) INTEGRATED CIRCUIT MEMORY DEVICES HAVING VERTICAL-CHANNEL TRANSISTORS THEREIN

(71) Applicant: Samsung Electronics Co., Ltd., Suwon-si (KR)

(72) Inventor: Moon Ju Hong, Suwon-si (KR)

(21) Appl. No.: 18/804,427

(22) Filed: Aug. 14, 2024

(30) Foreign Application Priority Data
Mar. 7, 2024 (KR) 10-2024-0032314

(51) Int. Cl. H10B 12/00

(52) U.S. Cl. CPC H10B 12/315; H10B 12/05

(57) ABSTRACT

An integrated circuit memory device includes a bit line, an etching stop film on the bit line, and a mold insulating structure film, which extends on the etching stop film and includes a channel trench extending in a second direction; the mold insulating structure film includes a first mold insulating film on the etching stop film, and a second mold insulating film on the first mold insulating film. A metal oxide pattern is provided, which extends on the bit line, and along a side wall of the channel trench. A word line extends on the metal oxide pattern, and a data storage pattern extends on the metal oxide pattern, and is connected to the metal oxide pattern. The second mold insulating film includes an upper surface and a bottom surface, which extend opposite to each other; the bottom surface of the second mold insulating film faces the bit line.

### REFERENCE TO PRIORITY APPLICATION

This application claims priority under 35 U.S.C. 119 to Korean Patent Application No. 10-2024-0032314, filed Mar. 7, 2024, the disclosure of which is hereby incorporated herein by reference.

### BACKGROUND

The present disclosure relates to integrated circuit memory devices and, more specifically, to integrated circuit memory devices having vertical channel transistors (VCTs) therein.

There is an ongoing need to increase a degree of integration of integrated circuit memory devices to satisfy excellent performance and low price required by consumers. In the case of an integrated circuit memory device, because the degree of integration is an important factor in determining the price of a product, an increased degree of integration is particularly required.

In the case of a two-dimensional or planar integrated circuit memory device, the degree of integration is mainly determined by an area occupied by unit memory cells, and is therefore greatly affected by the level of fine pattern forming technology. However, since ultra-expensive apparatuses are required to miniaturize the pattern, the degree of integration of the two-dimensional integrated circuit memory device is increasing, but is still limited. Accordingly, integrated circuit memory devices that include vertical channel transistors having channels extending in a vertical direction have been proposed.

### SUMMARY

Aspects of the present disclosure provide an integrated circuit memory device having improved degree of integration and electrical characteristics.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided an integrated circuit memory device including: a bit line extending in a first direction on a substrate, an etching stop film on the bit line, a mold insulating structure film, which is disposed on the etching stop film and includes a channel trench extending in a second direction, a metal oxide pattern, which is disposed on the bit line and extends along a side wall of the channel trench, a word line, which is disposed on the metal oxide pattern and extends in the second direction, and a data storage pattern, which extends on the metal oxide pattern, and is connected to the metal oxide pattern. The mold insulating structure film includes a first mold insulating film on the etching stop film, and a second mold insulating film on the first mold insulating film. The second mold insulating film includes an upper surface and a bottom surface that are opposite to each other in a third direction; the bottom surface of the second mold insulating film faces the bit line, and a height from an upper surface of the bit line to an uppermost part of the metal oxide pattern is greater than a height from the upper surface of the bit line to the upper surface of the second mold insulating film.

According to another aspect of the present disclosure, there is provided an integrated circuit memory device including: a bit line extending in a first direction on a substrate, an etching stop film on the bit line, a mold insulating structure film, which is disposed on the etching stop film and includes a channel trench extending in a second direction, a metal oxide pattern, which extends on the bit line and extends along a side wall of the channel trench, a word line, which extends on the metal oxide pattern, and extends in the second direction, and a data storage pattern, which extends on the metal oxide pattern, and is connected to the metal oxide pattern. The mold insulating structure film includes a first mold insulating film, a second mold insulating film, and a third mold insulating film that are sequentially stacked on the etching stop film. The second mold insulating film extends between the first mold insulating film and the third mold insulating film, and the second mold insulating film includes an upper surface and a bottom surface, which are opposite to each other in a third direction. The bottom surface of the second mold insulating film faces the bit line, and a height from an upper surface of the bit line to an uppermost part of the metal oxide pattern is greater than a height from the upper surface of the bit line to the bottom surface of the second mold insulating film.

According to still another aspect of the present disclosure, there is provided an integrated circuit memory device including a bit line extending in a first direction on a substrate, a first metal oxide pattern and a second metal oxide pattern, which extend on the bit line and are spaced apart from each other in the first direction, a mold insulating structure film extending on the bit line, and between the first metal oxide pattern and the second metal oxide pattern, a first word line, which extends on the first metal oxide pattern and in a second direction, a second word line, which extends on the second metal oxide pattern, and in the second direction, and a data storage pattern, which extends on the first metal oxide pattern and the second metal oxide pattern, and is connected to the first metal oxide pattern and the second metal oxide pattern. The mold insulating structure film includes a first mold insulating film, a second mold insulating film, and a third mold insulating film that are sequentially stacked on the bit line; the second mold insulating film extends between the first mold insulating film and the third mold insulating film. The second mold insulating film and the third mold insulating film may each include: an upper surface and a bottom surface that are opposite to each other in a third direction, and where the upper surface of the second mold insulating film faces the bottom surface of the third mold insulating film, and a width of the upper surface of the second mold insulating film in the first direction is greater than a width of the bottom surface of the third mold insulating film in the first direction.

### BRIEF DESCRIPTION OF DRAWINGS

The above and other aspects and features of the present disclosure will become more apparent by describing in detail illustrative embodiments thereof with reference to the attached drawings, in which:

FIG. 1 is a layout diagram for explaining an integrated circuit memory device according to some embodiments.

FIG. 2 is a cross-sectional view taken along lines A-A and B-B of FIG. 1.

FIG. 3 is a cross-sectional view taken along lines C-C and D-D of FIG. 1.

FIG. 4 is an enlarged view of a portion P of FIG. 2.

FIGS. 5 to 7 are diagrams for explaining an integrated circuit memory device according to some embodiments.

FIGS. 8 to 12 are diagrams for explaining an integrated circuit memory device according to some embodiments.

FIGS. 13 to 17 are diagrams for explaining an integrated circuit memory device according to some embodiments.

FIGS. 18 and 19 are diagrams for explaining an integrated circuit memory device according to some embodiments.

FIGS. 20 to 29 are intermediate stage diagrams for explaining a method for fabricating an integrated circuit memory device according to some embodiments.

FIGS. 30 to 32 are intermediate stage diagrams for explaining a method for fabricating an integrated circuit memory device according to some embodiments.

FIGS. 33 to 37 are intermediate stage diagrams for explaining a method for fabricating an integrated circuit memory device according to some embodiments.

### DETAILED DESCRIPTION OF THE EMBODIMENTS

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure.

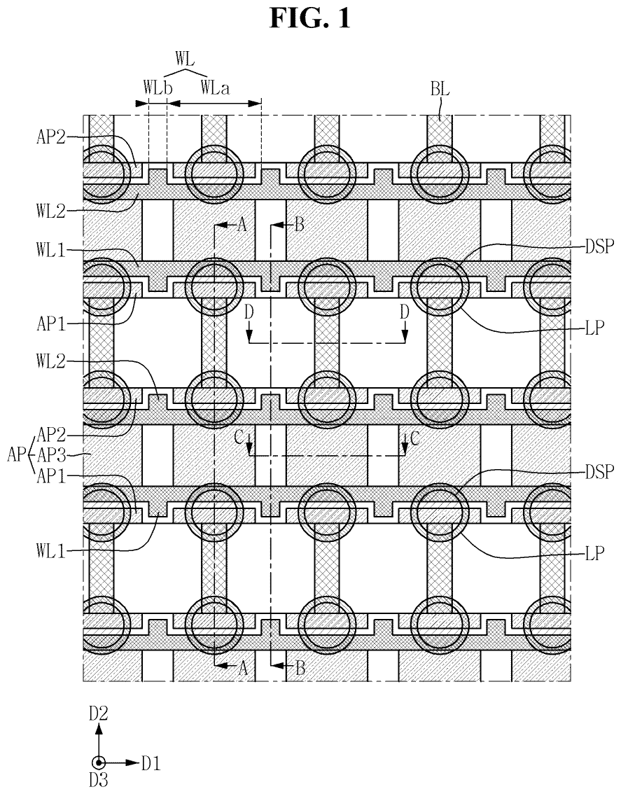

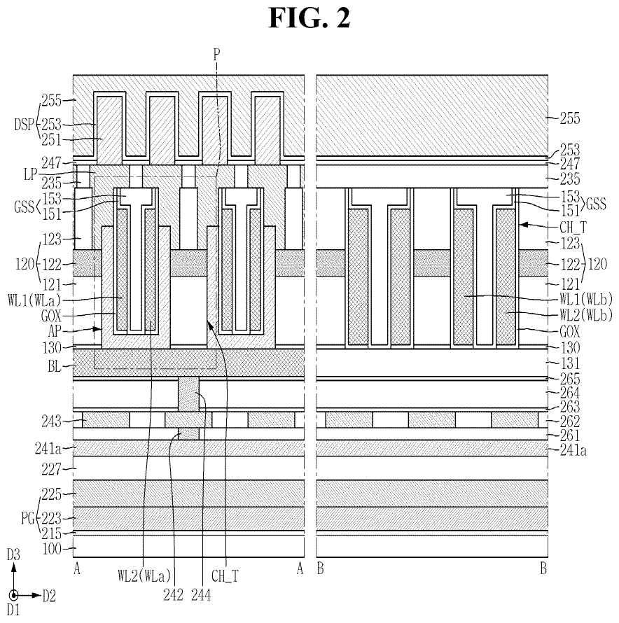

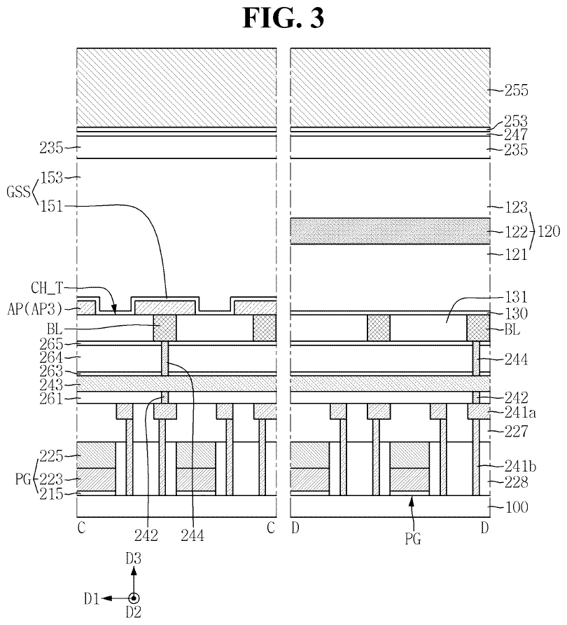

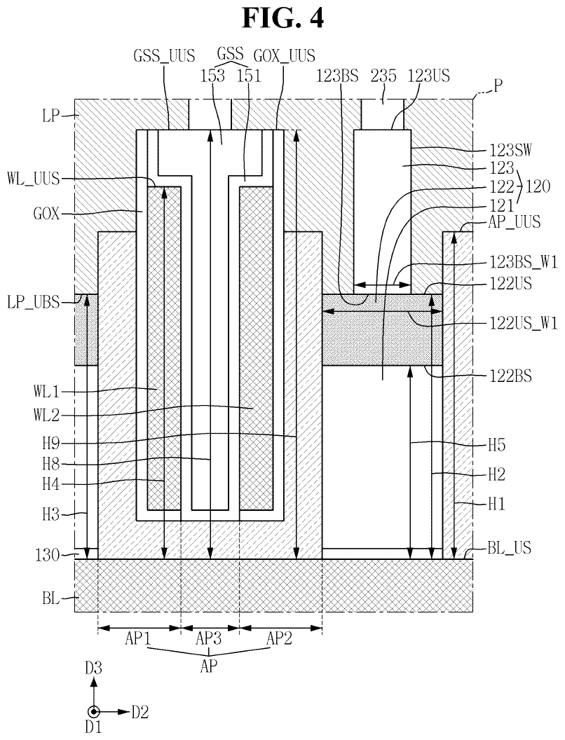

FIG. 1 is a layout diagram for explaining an integrated circuit memory device according to some embodiments. FIG. 2 is a cross-sectional view taken along lines A-A and B-B of FIG. 1. FIG. 3 is a cross-sectional view taken along lines C-C and D-D of FIG. 1. FIG. 4 is an enlarged view of a portion P of FIG. 2. The integrated circuit memory device according to an embodiment of the present disclosure may include memory cells that utilize vertical channel transistors (VCTs).

Referring to FIGS. 1 to 4, the integrated circuit memory device according to some embodiments may include a substrate 100, a peri-gate structure PG, bit lines BL, word lines WL, oxide pattern structures AP, mold insulating structure films 120, and data storage patterns DSP. The substrate 100 may be a silicon substrate, or may include other materials, for example, but not limited to, silicon germanium, indium antimonide, lead telluride, indium arsenide, indium phosphide, gallium arsenide or gallium antimonide.

The peri-gate structure PG may extend on the substrate 100. The substrate 100 may include a cell array region and a peripheral circuit region. The peri-gate structure PG may extend over the cell array region and the peripheral circuit region. In other words, a part of the peri-gate structure PG may extend in the cell array region of the substrate 100, and the rest of the peri-gate structure PG may extend in the peripheral circuit region of the substrate 100.

The peri-gate structure PG may be included in a sensing transistor, a transfer transistor, a drive transistor, etc. It goes without saying that the types of transistors disposed in the cell array region and the peripheral circuit region may vary depending on the design and layout of the integrated circuit memory device. The peri-gate structure PG may include a peri-gate insulating film 215, a peri-lower conductive pattern 223, and a peri-upper conductive pattern 225. The peri-gate insulating film 215 may include a silicon oxide film, a silicon oxynitride film, a high dielectric constant insulating film having a higher dielectric constant than a silicon oxide film, or a combination thereof. The high dielectric constant insulating film may include, for example, but not limited to, at least one of metal oxide, metal oxynitride, metal silicon oxide, and metal silicon oxynitride.

The peri-lower conductive pattern 223 and the peri-upper conductive pattern 225 may each include a conductive material. For example, the peri-lower conductive pattern 223 and the peri-upper conductive pattern 225 may each include at least one of a doped semiconductor material, conductive metal nitride, conductive metal silicon nitride, metal carbonitride, conductive metal silicide, conductive metal oxide, two-dimensional (2D) material, metal, and metal alloy. Although the peri-gate structure PG is shown to include a plurality of conductive patterns, the embodiment is not limited thereto.

In the semiconductor device according to some embodiments, the two-dimensional material may be a metallic material and/or a semiconductor material. The 2D material may include a 2D allotrope or a 2D compound, and may include, but not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials are only listed as an example, the 2D materials that may be included in the integrated circuit memory device of the present disclosure are not limited by the above-mentioned materials.

A first peri-lower insulating film 227 and a second peri-lower insulating film 228 are disposed on the substrate 100. Each of the first peri-lower insulating film 227 and the second peri-lower insulating film 228 may be made up of an insulating material. A first peri-wiring line 241a and a peri-contact plug 241b may extend inside the first peri-lower insulating film 227 and the second peri-lower insulating film 228. Although the first peri-wiring line 241a and the peri-contact plug 241b are shown as being different films from each other, the present disclosure is not limited thereto. A boundary between the first peri-wiring line 241a and the peri-contact plug 241b may not be distinguished. The first peri-wiring line 241a and the peri-contact plug 241b each include a conductive material.

The first peri-upper insulating film 261 and the second peri-upper insulating film 262 may extend on the first peri-wiring line 241a and the peri-contact plug 241b. The first peri-upper insulating film 261 and the second peri-upper insulating film 262 may each be made up of an insulating material. A second peri-wiring line 243 and a peri-via plug 242 are disposed on the first peri-wiring line 241a. The peri-via plug 242 may extend inside the first peri-upper insulating film 261. The second peri-wiring line 243 may extend inside the second peri-upper insulating film 262.

The second peri-wiring line 243 and the peri-via plug 242 may be connected to the first peri-wiring line 241a. The peri-via plug 242 may connect the first peri-wiring line 241a and the second peri-wiring line 243. The second peri-wiring line 243 and the peri-via plug 242 each include a conductive material. Although the second peri-wiring line 243 and the peri-via plug 242 are shown as being different films from each other, the embodiment is not limited thereto. A boundary between the second peri-wiring line 243 and the peri-via plug 242 may not be distinguished.

A third peri-upper insulating film 263, a fourth peri-upper insulating film 264, and a fifth peri-upper insulating film 265 may be sequentially disposed on the second peri-wiring line 243. The third peri-upper insulating film 263, the fourth peri-upper insulating film 264, and the fifth peri-upper insulating film 265 may each be made of an insulating material. The fourth peri-upper insulating film 264 may be made of an insulating material different from those of the third peri-upper insulating film 263 and the fifth peri-upper insulating film 265. For example, although the fourth peri-upper insulating film 264 may be made of an oxide-based insulating material, and the third peri-upper insulating film 263 and the fifth peri-upper insulating film 265 may be made of a nitride-based insulating material, the embodiment is not limited thereto.

A cell connection plug 244 may extend inside the third peri-upper insulating film 263, the fourth peri-upper insulating film 264, and the fifth peri-upper insulating film 265. The cell connection plug 244 may be connected to the second peri-wiring line 243. The cell connection plug 244 includes a conductive material. It goes without saying that the peri-upper insulating films 261, 262, 263, 264, and 265 made up of a single film may extend in the cell connection plug 244, unlike the shown example.

The bit lines BL are disposed on the peri-gate structure PG. More specifically, the bit lines BL may extend on the fifth peri-upper insulating film 265. For example, the bit lines BL may make contact with the fifth peri-upper insulating film 265. The bit line BL may extend long in a second direction D2. Adjacent bit lines BL may be spaced apart in a first direction D1. The bit line BL includes a long side wall extending in the second direction D2, and a short side wall extending in the first direction D1. Although it is not shown, each bit line BL may extend from the cell array region to the peripheral circuit region. Ends of each bit line BL may extend on the peripheral circuit region of the substrate 100.

Each bit line BL may extend on the cell connection plug 244. Each bit line BL may be connected to the cell connection plug 244. Each bit line BL may include, for example, at least one of doped semiconductor material, conductive metal nitride, conductive metal silicon nitride, metal carbonitride, conductive metal silicide, conductive metal oxide, two-dimensional material, metal and metal alloy. Although each bit line BL is shown as being a single film, the embodiment is not limited thereto.

The cell lower insulating film 131 may extend on the fifth peri-upper insulating film 265. The cell lower insulating film 131 is disposed between the bit lines BL spaced apart in the first direction D1. The cell lower insulating film 131 may be made up of an insulating material.

A mold insulating structure film 120 is disposed on the bit line BL and the cell lower insulating film 131. An etching stop film 130 may extend between the mold insulating structure film 120 and the cell lower insulating film 131. The mold insulating structure film 120 may include a first mold insulating film 121, a second mold insulating film 122, and a third mold insulating film 123.

The first mold insulating film 121, the second mold insulating film 122, and the third mold insulating film 123 may be sequentially provided in a stacked relationship on the bit line BL. The first mold insulating film 121, the second mold insulating film 122, and the third mold insulating film 123 may extend in the first direction D1.

The second mold insulating film 122 may extend between the first mold insulating film 121 and the third mold insulating film 123. The second mold insulating film 122 may include an upper surface 122US and a bottom surface 122BS that extend opposite to each other in the third direction D3. The bottom surface 122BS of the second mold insulating film may face the bit line BL.

The second mold insulating film 122 may extend on the first mold insulating film 121. The third mold insulating film 123 may extend on the second mold insulating film 122. The upper surface of the first mold insulating film 121 may be in contact with the bottom surface 122BS of the second mold insulating film. The upper surface 122US of the second mold insulating film may be in contact with the bottom surface 123BS of the third mold insulating film. For example, a height H5 from the upper surface BL_US of the bit line to the bottom surface 122BS of the second mold insulating film may be smaller than a height from the upper surface BL_US of the bit line to the bottom surface 123BS of the third mold insulating film.

The first mold insulating film 121 may extend on the etching stop film 130. For example, the etching stop film 130 may extend between the first mold insulating film 121, the bit line BL and the cell lower insulating film 131.

In FIG. 4, a width 122US_W1 of the upper surface 122US of the second mold insulating film in the second direction D2 may be greater than a width 123BS_W1 of the bottom surface 123BS of the third mold insulating film in the second direction D2. In other words, between the oxide pattern structures AP adjacent in the second direction D2, the width 122US_W1 of the upper surface 122US of the second mold insulating film in the first direction D1 may be greater than the width 123BS_W1 of the bottom surface 123BS of the third mold insulating film in the first direction D1. The second mold insulating film 122 and the third mold insulating film 123 may have a “T” shape rotated by 180 degrees.

The mold insulating structure film 120 and the etching stop film 130 may each be made up of an insulating material. Each of the first mold insulating film 121 and the second mold insulating film 122 may include different materials. The first mold insulating film 121 may include a silicon oxide-based insulating material, and may include, for example, silicon oxide. The second mold insulating film 122 may include a silicon nitride-based insulating material, and may include, for example, silicon nitride. The third mold insulating film 123 may include the same material as the first mold insulating film 121.

The etching stop film 130 may include a material having an etching selectivity with respect to the mold insulating structure film 120. For example, the etching stop film 130 may include an insulating material having an etching selectivity with respect to the first mold insulating film 121.

The mold insulating film 120 may include a plurality of channel trenches CH_T. Each channel trench CH_T may extend long in the first direction D1. Adjacent channel trenches CH_T may be spaced apart in the second direction D2. Each channel trench CH_T intersects the bit line BL. One channel trench CH_T may expose a plurality of bit lines BL adjacent to each other in the first direction D1.

The bottom surface of each channel trench CH_T may be defined by the bit line BL and the cell lower insulating film 131. A side wall of each channel trench CH_T may be defined by a mold insulating structure film 120 and an etching stop film 130. The side walls of the channel trench CH_T may be the side walls of the mold insulating structure film 120 and the side walls of the etching stop film 130. For example, the side walls of the channel trench CH_T may be the side walls of the etching stop film 130, the side walls of the first mold insulating film 121, and the side walls of the second mold insulating film 122.

An oxide pattern structure AP may extend on each bit line BL. A plurality of oxide pattern structures AP may be connected to one bit line BL. The plurality of oxide pattern structures AP disposed on one bit line BL may be spaced apart in the second direction D2. The oxide pattern structure AP may extend within the channel trench CH_T and in the first direction D1. A plurality of oxide pattern structures AP may extend within one channel trench CH_T and be spaced apart from each other in the first direction D1.

For example, the oxide pattern structures AP may be arranged two-dimensionally along the first direction D1 and the second direction D2 that intersect each other. The oxide pattern structure AP may include a first metal oxide pattern AP1, a second metal oxide pattern AP2, and a third metal oxide pattern AP3. The third metal oxide pattern AP3 may connect the first metal oxide pattern AP1 and the second metal oxide pattern AP2. The first metal oxide pattern AP1 and the second metal oxide pattern AP2 may be spaced apart in the second direction D2.

The first metal oxide pattern AP1, the second metal oxide pattern AP2, and the third metal oxide pattern AP3 may extend on the bit line BL. The first metal oxide pattern AP1, the second metal oxide pattern AP2, and the third metal oxide pattern AP3 may be connected to the bit line BL. The first metal oxide pattern AP1, the second metal oxide pattern AP2, and the third metal oxide pattern AP3 may be in contact with the upper surface BL_US of the bit line.

The oxide pattern structure AP may extend along the side walls and the bottom surface of the channel trench CH_T. In a cross-sectional views such as FIGS. 2 and 4, the oxide pattern structure AP may have a “U” shape. For example, the third metal oxide pattern AP3 may extend along the bottom surface of the channel trench CH_T, and the first metal oxide pattern AP1 and the second metal oxide pattern AP2 may extend along a part of the bottom surface of the channel trench CH_T and the side wall of the channel trench CH_T.

The oxide pattern structure AP may include a first oxide pattern structure AP and a second oxide pattern structure AP adjacent to each other in the second direction D2. The mold insulating structure film 120 may extend between the first oxide pattern structure AP and the second oxide pattern structure AP adjacent to each other in the second direction D2.

For example, the mold insulating structure film 120 may extend between the first metal oxide pattern AP1 of the first oxide pattern structure AP and the second metal oxide pattern AP2 of the second oxide pattern structure AP. For example, the first metal oxide pattern AP1 and the second metal oxide pattern AP2 may be in contact with the mold insulating structure film 120. Specifically, a part of the oxide pattern structure AP may be in contact with the etching stop film 130, the first mold insulating film 121, and the second mold insulating film 122.

In FIG. 4, an uppermost part AP_UUS of the oxide pattern structure may be an uppermost part of the first metal oxide pattern AP1. The uppermost part AP_UUS of the oxide pattern structure may be an uppermost part of the second metal oxide pattern AP2. A height H1 from the upper surface BL_US of the bit line to the uppermost part AP_UUS of the oxide pattern structure may be greater than a height H5 from the upper surface BL_US of the bit line to the bottom surface 122BS of the second mold insulating film. The height H1 from the upper surface BL_US of the bit line to the uppermost part AP_UUS of the oxide pattern structure may be greater than a height H2 from the upper surface BL_US of the bit line to the upper surface 122US of the second mold insulating film. For example, a part of the oxide pattern structure AP that protrudes beyond the upper surface 122US of the second mold insulating film in the third direction D3 may not be in contact with the third mold insulating film 123.

In the integrated circuit memory device according to some embodiments, the oxide pattern structure AP may include an oxide semiconductor material. The oxide pattern structure AP may include, for example, one of IGZO (indium gallium zinc oxide), impurity-doped IZO (indium zinc oxide), InO (indium oxide), ZnO (zinc oxide), GaO (gallium oxide), SnO (tin oxide), AZO (aluminum tin oxide), and ITO (indium tin oxide). In the impurity-doped IZO (indium zinc oxide), the doped impurities may include, for example, at least one of magnesium (Mg), strontium (Sr), barium (Ba), scandium (Sc), yttrium (Y), lanthanum (La), titanium (Ti), zirconium (Zr), hafnium (Hf), aluminum (AI), tin (Sn), and tantalum (Ta).

IGZO (indium gallium zinc oxide) included in the oxide pattern structure AP may be Ga-rich IGZO, In-rich IGZO or IGZO (In:Ga:Zn=1:1:1). The Ga-rich IGZO may have a higher ratio of gallium than IGZO (In:Ga:Zn=1:1:1), and a lower ratio of indium than IGZO (In:Ga:Zn=1:1:1). The In-rich IGZO may have a higher ratio of indium than IGZO (In:Ga:Zn=1:1:1), and a lower ratio of gallium than IGZO (In:Ga:Zn=1:1:1). However, the materials included in the oxide pattern structure AP are not limited thereto.

The word line WL may extend on the oxide pattern structure AP. The word line WL may extend inside the channel trench CH_T. The word line WL may include a first word line WL1 and a second word line WL2. For example, the first word line WL1 and the second word line WL2 may extend on the oxide pattern structure AP. Further, the first word line WL1 and the second word line WL2 may extend inside the channel trench CH_T. Each of the first word line WL1 and the second word line WL2 may extend in the first direction D1. The first word line WL1 and the second word line WL2 may be alternately arranged in the second direction D2. The first word line WL1 and the second word line WL2 may be spaced apart in the second direction D2. The first word line WL1 and the second word line WL2 may be spaced apart from the bit line BL in the third direction D3. The first word line WL1 and the second word line WL2 may intersect the bit line BL.

Each of the first word line WL1 and the second word line WL2 may extend on the first metal oxide pattern AP1 and the second metal oxide pattern AP2. The first word line WL1 may include an inner side wall that faces the mold insulating structure film 120, and an outer side wall opposite to the inner side wall in the second direction D2. A boundary between the first metal oxide pattern AP1 and the third metal oxide pattern AP3 may be an extension line of the outer side wall of the first word line WL1 extending in the third direction D3.

The second word line WL2 may include an inner side wall that faces the mold insulating structure film 120, and an outer side wall opposite to the inner side wall in the second direction D2. A boundary between the second metal oxide pattern AP2 and the third metal oxide pattern AP3 may be an extension line of the outer side wall of the second word line WL2 extending in the third direction D3.

In some embodiments, the first word line WL1 and the second word line WL2 may extend between the first metal oxide pattern AP1 and the second metal oxide pattern AP2. The first word line WL1 may be closer to the first metal oxide pattern AP1 than the second metal oxide pattern AP2. The second word line WL2 may be closer to the second metal oxide pattern AP2 than to the first metal oxide pattern AP1.

Each of the first word line WL1 and the second word line WL2 may have a width in the second direction D2. The width of the first word line WL1 in the second direction D2 in the portion which overlaps the oxide pattern structure AP in the first direction D1 may be different from the width of the first word line WL1 in the portion which does not overlap the oxide pattern structure AP in the second direction D2. The width of the second word line WL2 in the second direction D2 in the portion which overlaps the oxide pattern structure AP in the first direction D1 may be different from the width of the second word line WL2 in the second direction D2 in the portion which does not overlap the oxide pattern structure AP in the first direction D1.

For example, each of the first word line WL1 and the second word line WL2 may include a first portion WLa of the word line and a second portion WLb of the word line. The width of the first portion WLa of the word line in the second direction D2 may be smaller than the width of the second portion WLb of the word line in the second direction D2.

The first portion WLa of the word line may extend on the oxide pattern structure AP. Specifically, the first word line WL1 disposed on the first metal oxide pattern AP1 may be the first portion WLa of the word line. The second word line WL2 disposed on the second metal oxide pattern AP2 may be the first portion WLa of the word line. Each of the first word line WL1 and the second word line WL2 may include the first portion WLa of the word line and the second portion WLb of the word line that are alternately arranged along the first direction D1. Each oxide pattern structure AP may extend between the second portions WLb of the word lines adjacent in the first direction D1. In the first word line WL1, each first metal oxide pattern AP1 may extend between the second portions WLb of the word lines adjacent in the first direction D1. In the second word line WL2, each second metal oxide pattern AP2 may extend between the second portions WLb of the word lines adjacent in the second direction D2. The second portion WLb of the word line may not extend on the oxide pattern structure AP. A height of the first portion WLa of the word line in the third direction D3 may be smaller than a height of the second portion WLb of the word line in the third direction D3.

The first word line WL1 and the second word line WL2 may include a conductive material. For example, the first word line WL1 and the second word line WL2 may include at least one of doped polysilicon, conductive metal nitride, conductive metal silicon nitride, metal carbonitride, conductive metal silicide, conductive metal oxide, two-dimensional material, metal, and metal alloy.

In FIG. 4, the uppermost part WL_UUS of the word line may be the uppermost part of the first word line WL1. The uppermost part WL_UUS of the word line may be the uppermost part of the second word line WL2. A height H4 from the upper surface BL_US of the bit line to the uppermost part WL_UUS of the word line may be greater than the height H1 from the upper surface BL_US of the bit line to the uppermost part AP_UUS of the oxide pattern structure. The height H4 from the upper surface BL_US of the bit line to the uppermost part WL_UUS of the word line may be identical to the height H1 from the upper surface BL_US of the bit line to the uppermost part AP_UUS of the oxide pattern structure.

A gate insulating film GOX may extend between the first word line WL1 and the oxide pattern structure AP, and between the second word line WL2 and the oxide pattern structure AP. The gate insulating film GOX may extend between the first word line WL1 and the first metal oxide pattern AP1, and between the second word line WL2 and the second metal oxide pattern AP2. The gate insulating film GOX may extend in the first direction D1 along with the first word line WL1 and the second word line WL2.

The gate insulating film GOX may extend in the third direction D3 between the first word line WL1 and the first metal oxide pattern AP1. The gate insulating film GOX may extend in the third direction D3 between the second word line WL2 and the second metal oxide pattern AP2.

The gate insulating film GOX may extend in the second direction D2 between the first word line WL1 and the first metal oxide pattern AP1. The gate insulating film GOX may extend in the second direction D2 between the second word line WL2 and the second metal oxide pattern AP2. In the integrated circuit memory device according to some embodiments, the gate insulating film GOX may not extend on the third metal oxide pattern AP3. In the cross-sectional views such as FIGS. 2 and 4, the gate insulating film GOX between the first word line WL1 and the first metal oxide pattern AP1 may be separated from the gate insulating film GOX between the second word line WL2 and the second metal oxide pattern AP2.

The gate insulating film GOX may include a silicon oxide film, a silicon oxynitride film, a high dielectric constant insulating film having a higher dielectric constant than the silicon oxide film, or a combination thereof. A part of the gate insulating film GOX may protrude beyond the uppermost part AP_UUS of the oxide pattern structure in the third direction D3. A part of the gate insulating film GOX may protrude beyond the uppermost part WL_UUS of the word line in the third direction D3.

In FIG. 4, a height H9 from the upper surface BL_US of the bit line to the uppermost part GOX_UUS of the gate insulating film may be greater than the height H1 from the upper surface BL_US of the bit line to the uppermost part AP_UUS of the oxide pattern structure. The height H9 from the upper surface BL_US of the bit line to the uppermost part GOX_UUS of the gate insulating film may be greater than the height H4 from the upper surface BL_US of the bit line to the uppermost part WL_UUS of the word line.

A gate separation pattern GSS may extend on the bit line BL and the cell lower insulating film 131. The gate separation pattern GSS may extend in the channel trench CH_T. The gate separation pattern GSS may extend on the oxide pattern structure AP and the word line WL.

The gate separation pattern GSS may be in contact with the oxide pattern structure AP. The gate separation pattern GSS may extend on the third metal oxide pattern AP3. The gate separation pattern GSS may be spaced apart from the bit line BL in the third direction D3. The gate separation pattern GSS may extend between the first word line WL1 and the second word line WL2 adjacent to each other in the second direction D2. The gate separation pattern GSS may be in contact with the first word line WL1 and the second word line WL2. The first word line WL1 and the second word line WL2 may be separated by the gate separation pattern GSS. The gate separation pattern GSS may extend in the first direction D1 between the first word line WL1 and the second word line WL2.

The first word line WL1 may extend between the gate separation pattern GSS and the oxide pattern structure AP. The second word line WL2 may extend between the gate separation pattern GSS and the oxide pattern structure AP. The first word line WL1 may extend between the gate separation pattern GSS and the first metal oxide pattern AP1. The second word line WL2 may extend between the gate separation pattern GSS and the second metal oxide pattern AP2.

The gate separation pattern GSS may include a horizontal part and a protruding part. The protruding part of the gate separation pattern GSS may protrude from the horizontal part of the gate separation pattern GSS toward the bit line BL in the third direction D3. The protruding part of the gate separation pattern GSS may be closer to the bit line BL than the horizontal part of the gate separation pattern GSS. The protruding part of the gate separation pattern GSS may extend in the third direction between the first word line WL1 and the second word line WL2. The protruding part of the gate separation pattern GSS may be in contact with the upper surface of the third metal oxide pattern AP3. The horizontal part of the gate separation pattern GSS may extend on the upper surfaces of the first word line WL1 and the second word line WL2. When cut in a cross section that intersects the first direction D1, the gate separation pattern GSS may have a “T” shape in the cross section.

The gate separation pattern GSS may include a gate separation liner 151 and a gate separation filling film 153. The gate separation liner 151 may extend along the upper surface of the first word line WL1 and the upper surface of the second word line WL2, the outer side wall of the first word line WL1, and the outer side wall of the second word line WL2. The gate separation liner 151 may extend along the third metal oxide pattern AP3. The gate separation liner 151 may be in contact with the third metal oxide pattern AP3. The gate separation liner 151 may extend along the gate insulating film GOX that protrudes beyond the upper surface of the first word line WL1 and the upper surface of the second word line WL2. Although the height from the upper surface BL_US of the bit line to the uppermost part of the gate separation liner 151 may be identical to the height H9 from the upper surface BL_US of the bit line to the uppermost part GOX_UUS of the gate insulating film, the embodiment is not limited thereto.

The gate separation filling film 153 may extend on the gate separation liner 151. The gate separation filling film 153 may be in contact with the gate separation liner 151. When cut in a cross section that intersects the first direction D1, the gate separation filling film 153 may have a “T” shape in that cross section. The height from the upper surface BL_US of the bit line to the uppermost part of the gate separation filling film 153 may be identical to the height from the upper surface BL_US of the bit line to the uppermost part of the gate separation liner 151, but the embodiment is not limited thereto.

The gate separation liner 151 and the gate separation filling film 153 may each be made up of an insulating material. Unlike the shown example, the gate separation pattern GSS may be a single film. The upper surface of the gate separation pattern GSS may extend at the same height as the upper surface of the mold insulating structure film 120 on the basis of the upper surface BL_US of the bit line, but the embodiment is not limited thereto.

A height H8 from the upper surface BL_US of the bit line to the uppermost part GSS_UUS of the gate separation pattern may be greater than the height H1 from the upper surface BL_US of the bit line to the uppermost part AP_UUS of the oxide pattern structure. The height H8 from the upper surface BL_US of the bit line to the uppermost part GSS_UUS of the gate separation pattern may be greater than the height H4 from the upper surface BL_US of the bit line to the uppermost part WL_UUS of the word line.

Landing pads LP may extend on the oxide pattern structure AP, the mold insulating structure film 120, the gate separation pattern GSS, and the gate insulating film GOX. The landing pad LP may extend on the first metal oxide pattern AP1, the second mold insulating film 122, the gate separation pattern GSS, and the gate insulating film GOX. The landing pad LP may extend on the second metal oxide pattern AP2, the second mold insulating film 122, the gate separation pattern GSS, and the gate insulating film GOX.

The landing pad LP may be in contact with the first metal oxide pattern AP1 and the second metal oxide pattern AP2. The landing pad LP may be connected to the first metal oxide pattern AP1 and the second metal oxide pattern AP2.

The landing pad LP may be in contact with the second mold insulating film 122. For example, the landing pad LP may be in contact with the upper surface 122US of the second mold insulating film. The landing pad LP may be in contact with the third mold insulating film 123. For example, the landing pad LP may be in contact with the side wall 123SW of the third mold insulating film.

The landing pad LP may include a horizontal part and a protruding part. The horizontal part of the landing pad LP may extend on the upper surface 123US of the third mold insulating film and the uppermost part GSS_UUS of the gate separation pattern. The protruding part of the landing pad LP may protrude from the horizontal part of the landing pad LP toward the bit line BL in the third direction D3. The protruding part of the landing pad LP may extend between the third mold insulating film 123 and the gate separation pattern GSS. The protruding part of the landing pad LP may be in contact with the upper surface 122US of the second mold insulating film and the uppermost part AP_UUS of the oxide pattern structure. The protruding part of the landing pad LP may be in contact with the side walls 123SW of the third mold insulating film, the side walls of the gate insulating film GOX, and the side walls of the oxide pattern structure AP.

A lowermost part LP_UBS of the landing pad may be in contact with the upper surface 122US of the second mold insulating film. For example, a height H3 from the upper surface BL_US of the bit line to the lowermost part LP_UBS of the landing pad may be identical to the height H2 from the upper surface BL_US of the bit line to the upper surface 122US of the second mold insulating film. For example, the height H3 from the upper surface BL_US of the bit line to the lowermost part LP_UBS of the landing pad may be smaller than the height H1 from the upper surface BL_US of the bit line to the uppermost part AP_UUS of the oxide pattern structure.

The landing pad LP may include a conductive material. The landing pad LP may include, for example, at least one of doped polysilicon, conductive metal nitride, conductive metal silicon nitride, metal carbonitride, conductive metal silicide, conductive metal oxide, two-dimensional material, metal, and metal alloy. Pad separation insulating patterns 235 may extend between the landing pads LP. The pad separation insulating patterns 235 may extend on the gate separation pattern GSS and the mold insulating structure film 120. The pad separation insulating patterns 235 may extend on the gate separation filling film 153 and the third mold insulating film 123. The pad separation insulating patterns 235 may be in contact with the upper surface of the gate separation filling film 153 and the upper surface 123US of the third mold insulating film. From viewpoint of a plan view that intersects the third direction D3, the landing pads LP may be arranged in the form a matrix along the second direction D2 and the first direction D1. Although the upper surface of the landing pad LP may extend on the same plane as the upper surface of the pad separation insulating pattern 235, the embodiment is not limited thereto.

The data storage patterns DSP may extend on the landing pads LP, respectively. The data storage patterns DSP may be in contact with all or part of the upper surfaces of the landing pads LP. The data storage patterns DSP may be connected to the landing pads LP. The data storage patterns DSP may be connected to the first metal oxide pattern AP1 and the second metal oxide pattern AP2, respectively. The data storage patterns DSP may be arranged in the form of a matrix along the second direction D2 and the first direction D1, as shown in FIG. 1. The data storage patterns DSP may completely overlap the landing pads LP or may partially overlap the landing pads LP in the third direction D3.

In some embodiments, the data storage patterns DSP may be a capacitor. The first metal oxide pattern AP1 and the second metal oxide pattern AP2 may each be connected to the capacitor. The data storage patterns DSP may include a capacitor dielectric film 253 interposed between the storage electrodes 251 and the plate electrode 255. In such a case, the storage electrode 251 may make contact with the landing pad LP. From viewpoint of a plan view, the storage electrode 251 may have various shapes such as a circular shape, an oval shape, a rectangular shape, a square shape, a rhombic shape, and a hexagonal shape. The storage electrode 251 may completely or partially overlap the landing pads LP. The storage electrodes 251 may be in contact with all or part of the upper surfaces of the landing pads LP. The storage electrodes 251 may penetrate the cell upper etching stop film 247. The cell upper etching stop film 247 may be made up of an insulating material.

In contrast, the data storage patterns DSP may be variable resistance patterns that may be switched between two resistance states by electrical pulses applied to the memory elements. For example, the data storage patterns DSP may include a phase-change material, perovskite compounds, transition metal oxide, magnetic materials, ferromagnetic materials or antiferromagnetic materials in which a crystalline state changes depending on the amount of current.

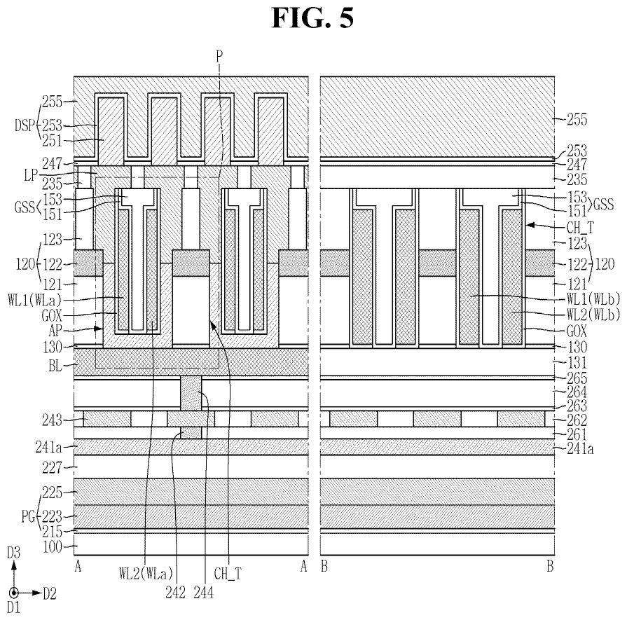

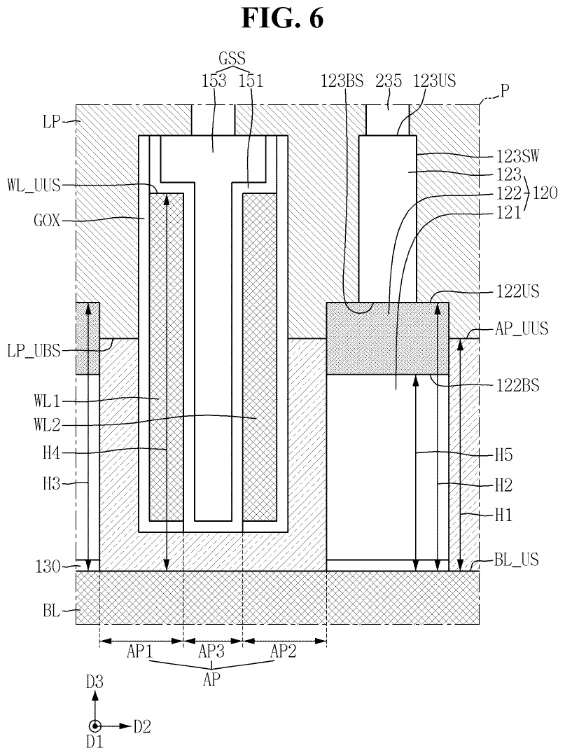

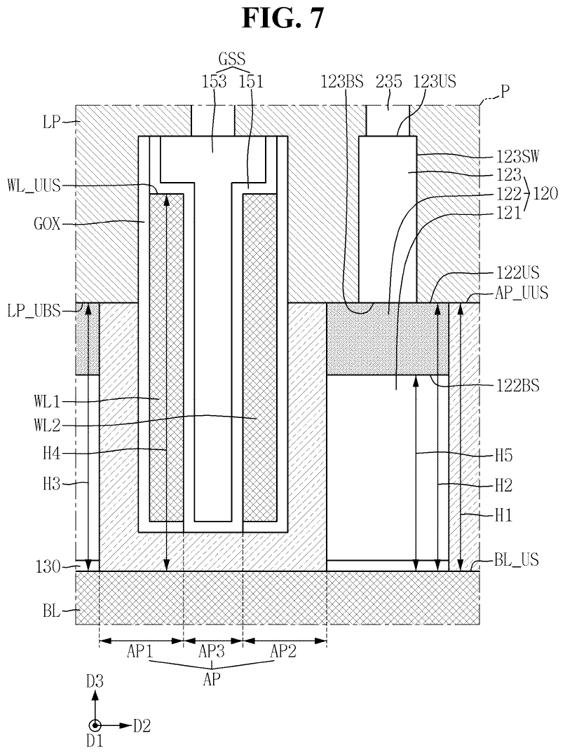

FIGS. 5 to 7 are diagrams for explaining an integrated circuit memory device according to some embodiments. For convenience of explanation, the explanation will focus on the points that are different from those explained using FIGS. 1 to 4. For reference, FIGS. 6 and 7 are enlarged views of a portion P of FIG. 5.

Referring to FIGS. 5 to 7, in the integrated circuit memory device according to some embodiments, the height H1 from the upper surface BL_US of the bit line to the uppermost part AP_UUS of the oxide pattern structure may be identical to the height H3 from the upper surface BL_US of the bit line to the lowermost part LP_UBS of the landing pad. The lowermost part LP_UBS of the landing pad may be in contact with the uppermost part AP_UUS of the oxide pattern structure. In FIG. 6, the height H1 from the upper surface BL_US of the bit line to the uppermost part AP_UUS of the oxide pattern structure may be smaller than the height H2 from the upper surface BL_US of the bit line to the upper surface 122US of the second mold insulating film.

The protruding part of the landing pad LP may be in contact with the uppermost part AP_UUS of the oxide pattern structure and the upper surface 122US of the second mold insulating film. The protruding part of the landing pad LP may be in contact with the side walls of the gate insulating film GOX, the side walls of the second mold insulating film 122, and the side walls 123SW of the third mold insulating film.

In FIG. 7, the height H1 from the upper surface BL_US of the bit line to the uppermost part AP_UUS of the oxide pattern structure may be identical to the height H2 from the upper surface BL_US of the bit line to the upper surface 122US of the second mold insulating film. The lowermost part LP_UBS of the landing pad may be in contact with the uppermost part AP_UUS of the oxide pattern structure and the upper surface 122US of the second mold insulating film. The protruding part of the landing pad LP may be in contact with the uppermost part AP_UUS of the oxide pattern structure and the upper surface 122US of the second mold insulating film. The protruding part of the landing pad LP may be in contact with the side walls of the gate insulating film GOX and the side walls 123SW of the third mold insulating film.

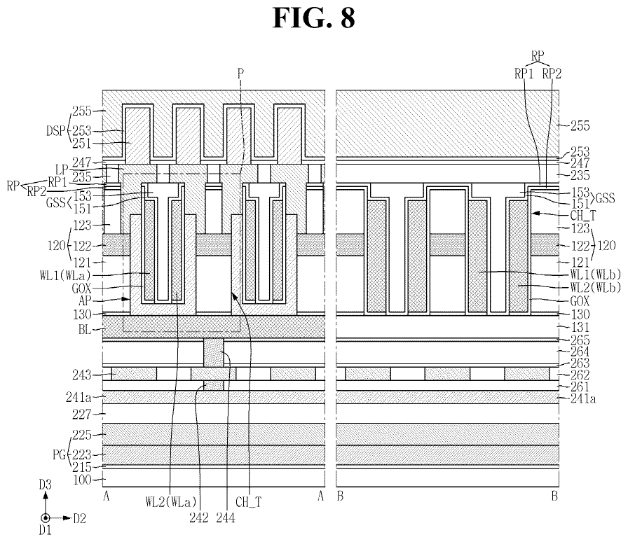

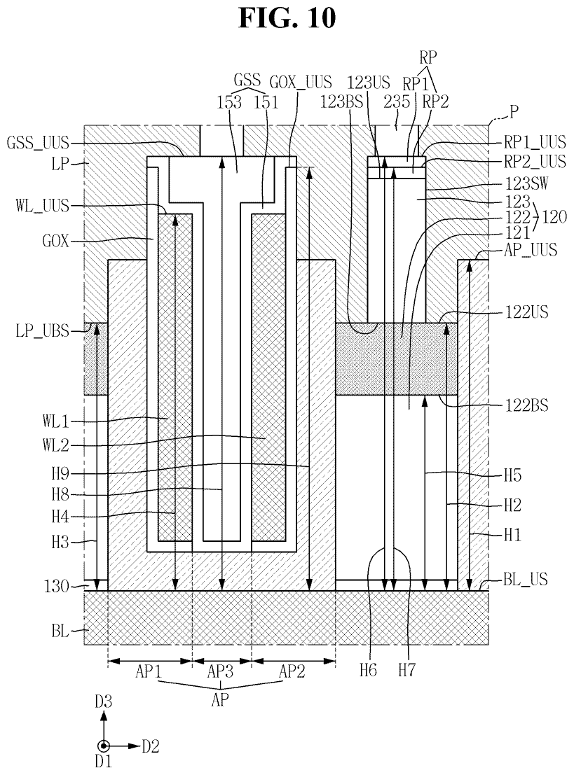

FIGS. 8 to 12 are diagrams for explaining an integrated circuit memory device according to some embodiments. For convenience of explanation, the explanation will focus on the points that are different from those explained using FIGS. 1 to 4. For reference, FIGS. 10 to 12 are enlarged views of a portion P of FIG. 8. Referring to FIGS. 8 to 12, the integrated circuit memory device according to some embodiments may further include a residual insulating pattern RP on the upper surface of the mold insulating structure film 120. The residual insulating pattern RP may extend on the upper surface 123US of the third mold insulating film. The residual insulating pattern RP may be in contact with the upper surface 123US of the third mold insulating film.

The residual insulating patterns RP may include a first residual insulating pattern RP1 and a second residual insulating pattern RP2. The first residual insulating pattern RP1 may extend on the second residual insulating pattern RP2. The second residual insulating pattern RP2 may extend on the upper surface 123US of the third mold insulating film. The bottom surface of the first residual insulating pattern RP1 may be in contact with the uppermost part RP2_UUS of the second residual insulating pattern. The bottom surface of the second residual insulating pattern RP2 may be in contact with the upper surface 123US of the third mold insulating film.

Although the width of the first residual insulating pattern RP1 in the second direction D2 and the width of the second residual insulating pattern RP2 in the second direction D2 may be identical to the width D2 of the third mold insulating film 123 in the second direction, the embodiment is not limited thereto. And, although a height H6 from the upper surface BL_US of the bit line to the uppermost part RP1_UUS of the first residual insulating pattern may be identical to a height H8 from the upper surface BL_US of the bit line to the uppermost part GSS_UUS of the gate separation pattern, this is only an example, and the embodiment is not limited thereto. Furthermore, although a height H7 from the upper surface BL_US of the bit line to the uppermost part RP2_UUS of the second residual insulating pattern may be identical to a height H9 from the upper surface BL_US of the bit line to the uppermost part GOX_UUS of the gate insulating film, this is only an example, and the embodiment is not limited thereto.

The first residual insulating pattern RP1 and the gate separation liner 151 may include the same material. The second residual insulating pattern RP2 and the gate insulating film GOX may include the same material. For example, the second residual insulating pattern RP2 may include a silicon oxide film, a silicon oxynitride film, a high dielectric constant insulating film having a higher dielectric constant than the silicon oxide film, or a combination thereof.

In other words, the first residual insulating pattern RP1 may be directly connected to the gate separation liner 151 to form a single first insulating liner. A portion of the first insulating liner disposed on the upper surface 123US of the third mold insulating film may be the first residual insulating pattern RP1. The second residual insulating pattern RP2 may be directly connected to the gate insulating film GOX to form a single second insulating liner. A portion of the second insulating liner disposed on the upper surface 123US of the third mold insulating film may be the second residual insulating pattern RP2.

The horizontal part of the gate separation pattern GSS may extend on the upper surface of the first word line WL1, the upper surface of the second word line WL2, and the uppermost part GOX_UUS of the gate insulating film. The gate separation liner 151 may extend at the uppermost part of the gate insulating film GOX_UUS. The height from the upper surface BL_US of the bit line to the uppermost part of the gate separation liner 151 may be greater than the height H9 from the upper surface BL_US of the bit line to the uppermost part GOX_UUS of the gate insulating film. The pad separation insulating pattern 235 may extend on the residual insulating pattern RP. The pad separation insulating pattern 235 may be in contact with the first residual insulating pattern RP1.

The horizontal part of the landing pad LP may be in contact with the gate separation liner 151 and the upper surface of the first residual insulating pattern RP1, but may not be in contact with the uppermost part GOX_UUS of the gate insulating film. The protruding part of the landing pad LP may be in contact with a side wall of the first residual insulating pattern RP1 and a side wall of the second residual insulating pattern RP2.

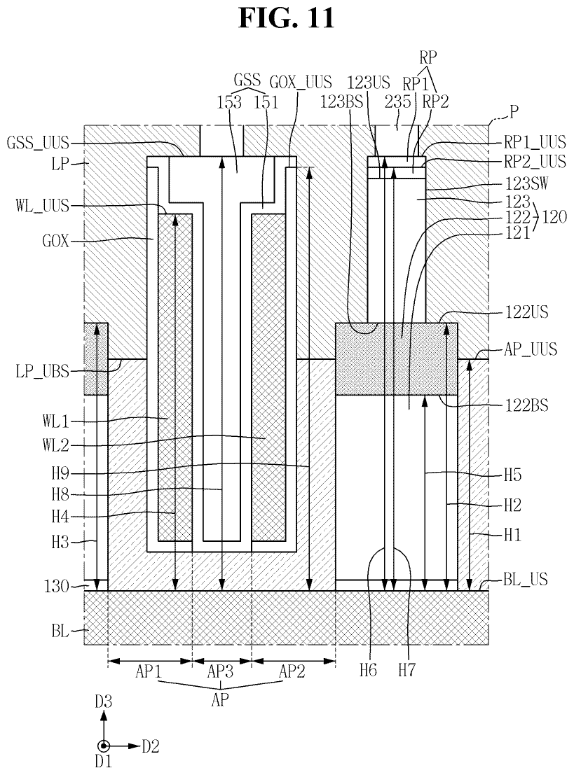

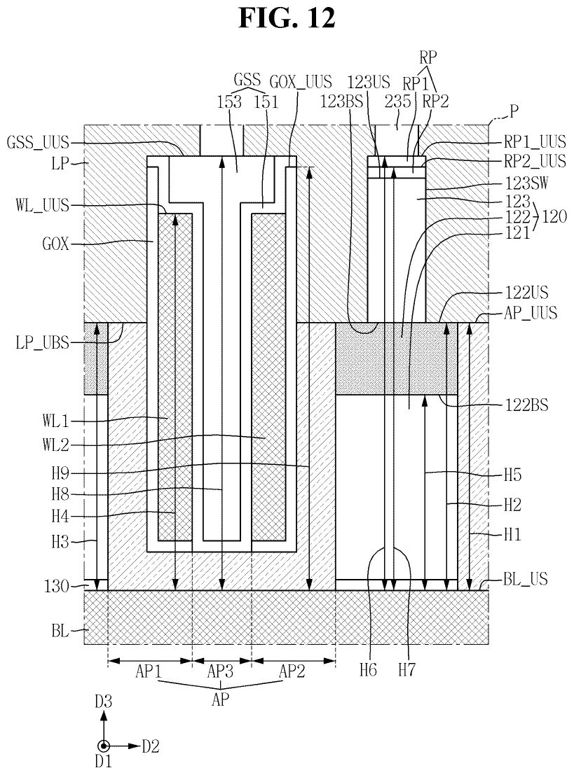

In FIG. 10, the height H1 from the upper surface BL_US of the bit line to the uppermost part AP_UUS of the oxide pattern structure may be greater than the height H2 from the upper surface BL_US of the bit line to the upper surface 122US of the second mold insulating film. In FIG. 11, the height H1 from the upper surface BL_US of the bit line to the uppermost part AP_UUS of the oxide pattern structure may be smaller than the height H2 from the upper surface BL_US of the bit line to the upper surface 122US of the second molded insulating film. In FIG. 12, the height H1 from the upper surface BL_US of the bit line to the uppermost part AP_UUS of the oxide pattern structure may be identical to the height H2 from the upper surface BL_US of the bit line to the upper surface 122US of the second mold insulating film.

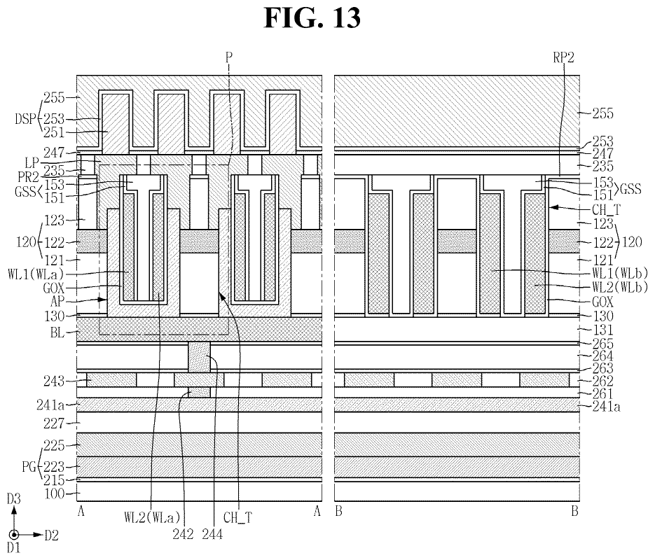

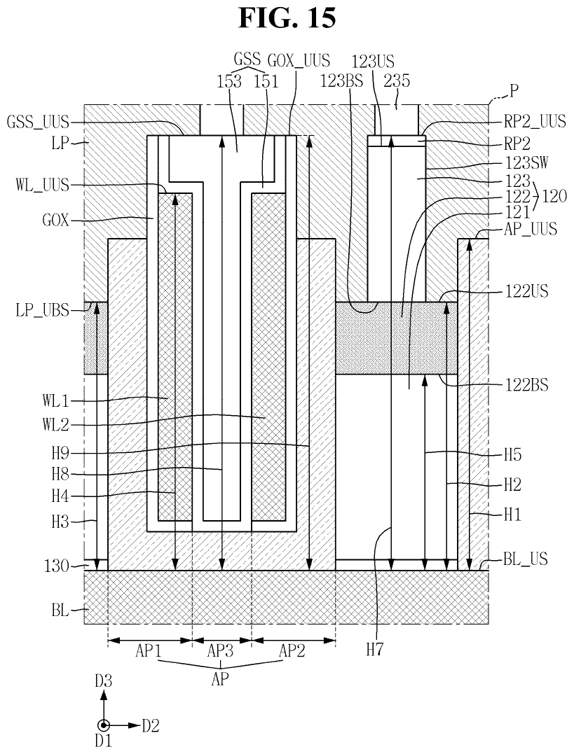

FIGS. 13 to 17 are diagrams for explaining an integrated circuit memory device according to some embodiments. For convenience of explanation, the explanation will focus on the points that are different from those explained using FIGS. 1 to 4. For reference, FIGS. 15 to 17 are enlarged views of a portion P of FIG. 13. Referring to FIGS. 13 to 17, in the integrated circuit memory device according to some embodiments, a second residual insulating pattern RP2 may extend on the mold insulating structure film 120. The second residual insulating pattern RP2 may extend on the upper surface 123US of the third mold insulating film. The bottom surface of the second residual insulating pattern RP2 may be in contact with the upper surface 123US of the third mold insulating film.

Although the width of the second residual insulating pattern RP2 in the second direction D2 may be identical to the width of the third mold insulating film 123 in the second direction D2, the embodiment is not limited thereto. And, although the height H7 from the upper surface BL_US of the bit line to the uppermost part RP2_UUS of the second residual insulating pattern may be identical to the height H9 from the upper surface BL_US of the bit line to the uppermost part GOX_UUS of the gate insulating film, this is only an example, and the embodiment is not limited thereto.

Furthermore, although the height H7 from the upper surface BL_US of the bit line to the uppermost part RP2_UUS of the second residual insulating pattern may be identical to the height H8 from the upper surface BL_US of the bit line to the uppermost part GSS_UUS of the gate separation pattern, this is only an example, and the embodiment is not limited thereto.

The second residual insulating pattern RP2 and the gate insulating film GOX may include the same material. For example, the second residual insulating pattern RP2 may include a silicon oxide film, a silicon oxynitride film, a high dielectric constant insulating film having a higher dielectric constant than the silicon oxide film, or a combination thereof. In other words, the second residual insulating pattern RP2 may be directly connected to the gate insulating film GOX to form a single second insulating liner. A portion of the second insulating liner disposed on the upper surface 123US of the third mold insulating film may be the second residual insulating pattern RP2.

The pad separation insulating pattern 235 may extend on the second residual insulating pattern RP2. The pad separation insulating pattern 235 may be in contact with the second residual insulating pattern RP2. A horizontal part of the landing pad LP may be in contact with the upper surface of the second residual insulating pattern RP2. The protruding part of the landing pad LP may be in contact with the side wall of the second residual insulating pattern RP2.

In FIG. 15, the height H1 from the upper surface BL_US of the bit line to the uppermost part AP_UUS of the oxide pattern structure may be greater than the height H2 from the upper surface BL_US of the bit line to the upper surface 122US of the second mold insulating film.

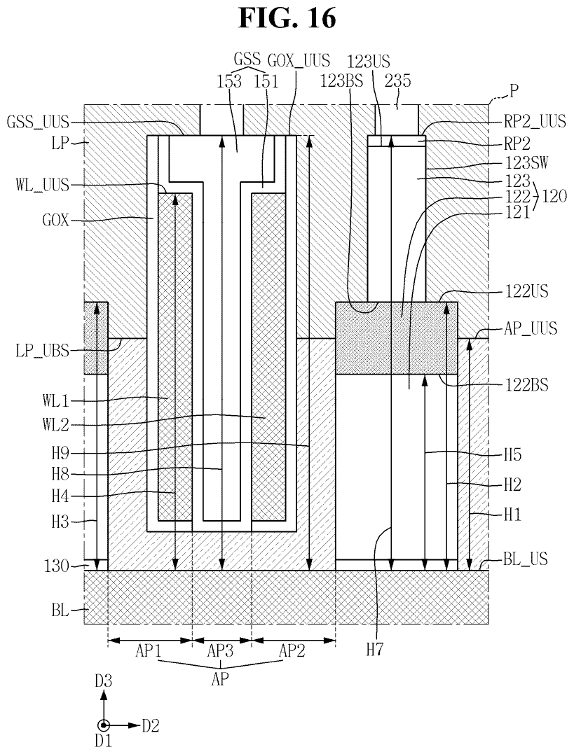

In FIG. 16, the height H1 from the upper surface BL_US of the bit line to the uppermost part AP_UUS of the oxide pattern structure may be smaller than the height H2 from the upper surface BL_US of the bit line to the upper surface 122US of the second molded insulating film. In this case, the second residual insulating pattern RP2 may extend on the mold insulating structure film 120.

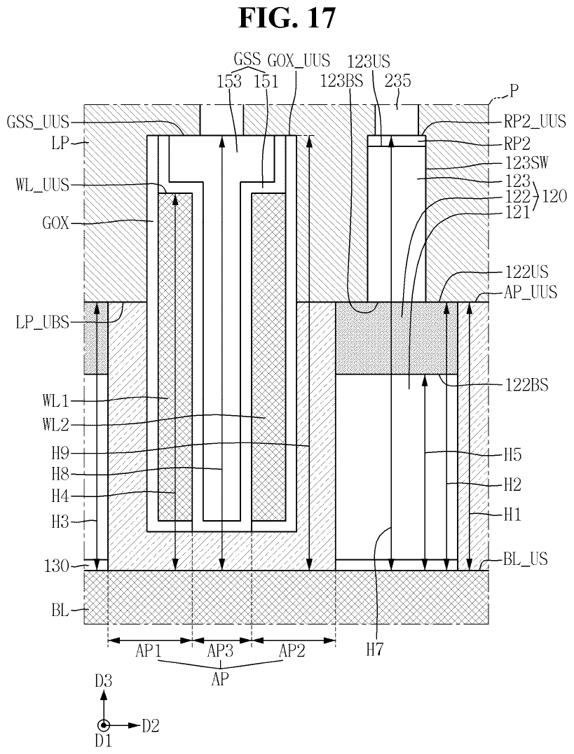

In FIG. 17, the height H1 from the upper surface BL_US of the bit line to the uppermost part AP_UUS of the oxide pattern structure may be identical to the height H2 from the upper surface BL_US of the bit line to the upper surface 122US of the second mold insulating film. In this embodiment, the second residual insulating pattern RP2 may extend on the mold insulating structure film 120.

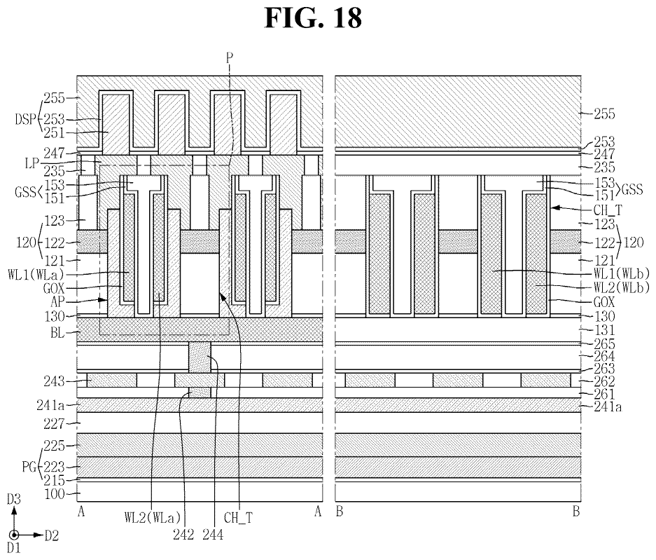

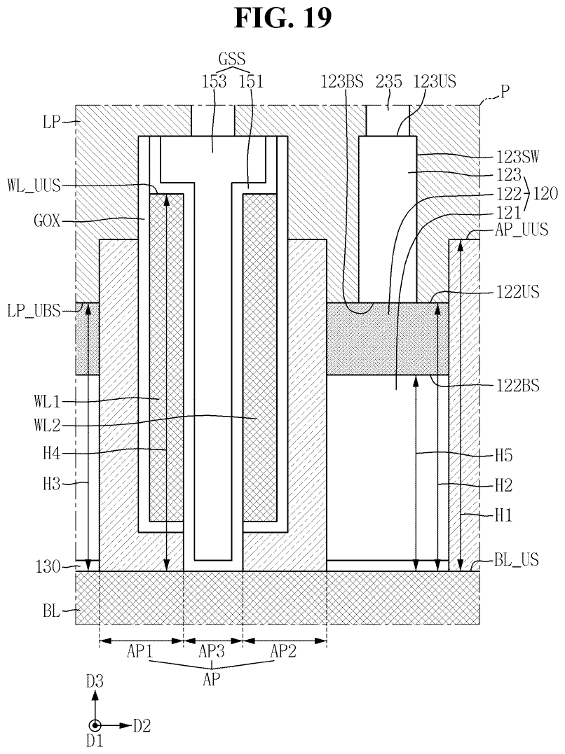

FIGS. 18 and 19 are diagrams for explaining an integrated circuit memory device according to some embodiments. For convenience of explanation, the explanation will focus on the points that are different from those explained using FIGS. 1 to 4. For reference, FIG. 19 is an enlarged view of a portion P of FIG. 18.

Referring to FIGS. 18 and 19, in the integrated circuit memory device according to some embodiments, the first metal oxide pattern AP1 and the second metal oxide pattern AP2, which are spaced apart in the second direction D2, are not connected inside the channel trench CH_T. The gate separation pattern GSS may be in contact with the bit line BL. The gate separation liner 151 may be in contact with the upper surface BL_US of the bit line. The first metal oxide pattern AP1 and the second metal oxide pattern AP2 may be spatially separated by the gate separation pattern GSS.

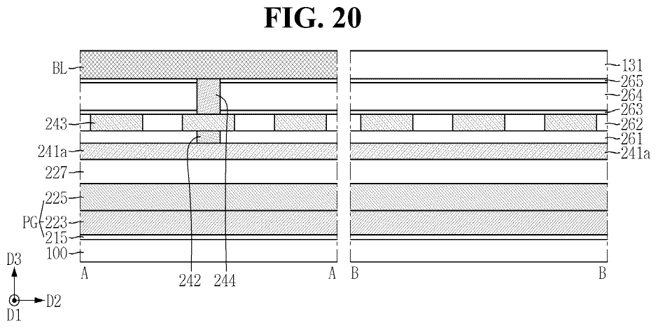

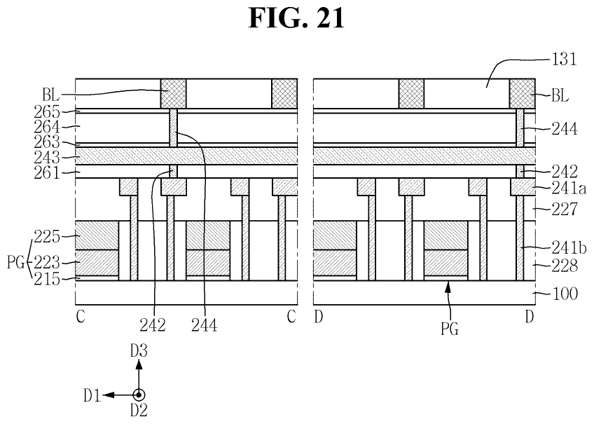

FIGS. 20 to 29 are intermediate stage diagrams for explaining a method for fabricating an integrated circuit memory device according to some embodiments. Referring to FIGS. 20 and 21, a peri-gate structure PG may be formed on the substrate 100. A first peri-wiring line 241a and a peri-contact plug 241b may be formed on the substrate 100. The peri-upper insulating films 261, 262, 263, 264 and 265 may be sequentially formed on the first peri-wiring line 241a and the peri-contact plug 241b. The second peri-wiring line 243, the peri-via plug 242 and the cell connection plug 244 may be formed inside the peri-upper insulating films 261, 262, 263, 264 and 265. The bit lines BL may then be formed on the fifth peri-upper insulating film 265. The bit line BL may extend long in the second direction D2 on the substrate 100. The cell lower insulating film 131 may be formed on the fifth peri-upper insulating film 265. The cell lower insulating film 131 may expose the upper surface BL_US of the bit line.

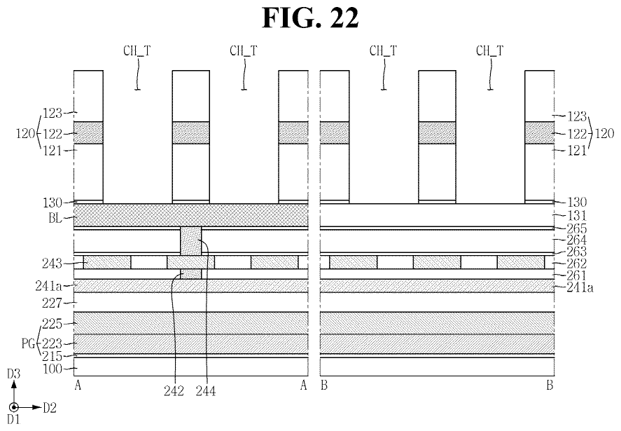

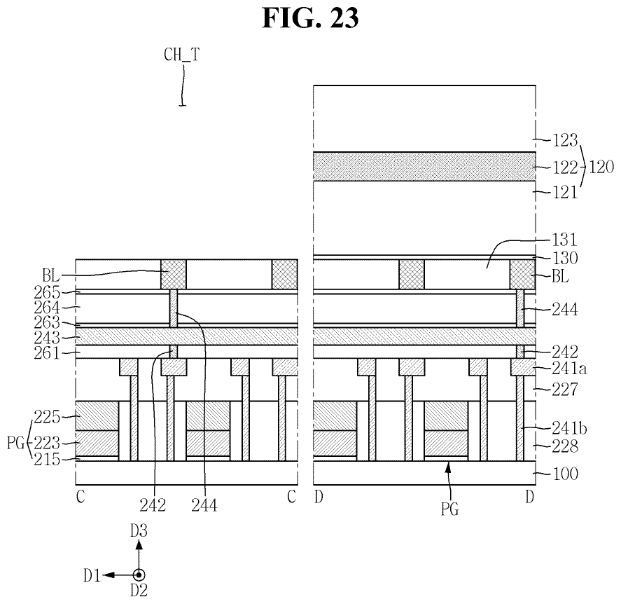

Referring to FIGS. 22 and 23, the mold insulating structure film 120 may be formed on the substrate 100. Specifically, the first mold insulating film 121, the second mold insulating film 122, and the third mold insulating film 123 may be formed sequentially on the bit line BL and the cell lower insulating film 131.

The etching stop film 130 may be formed between the mold insulating structure film 120, the bit line BL, and the cell lower insulating film 131, but is not limited thereto. The first mold insulating film 121 may be formed of a silicon oxide-based insulating material on the etching stop film 130. For example, the first mold insulating film 121 may be formed of silicon oxide. The second mold insulating film 122 may be formed of a silicon nitride-based insulating material, on the first mold insulating film 121. For example, the second mold insulating film 122 may be formed of silicon nitride. The third mold insulating film 123 may be formed of a silicon oxide-based insulating material, on the second mold insulating film 122. For example, the third mold insulating film 123 may be formed of silicon oxide. The mold insulating structure film 120 may include a plurality of channel trenches CH_T extending in the first direction D1. The channel trench CH_T may intersect the bit line BL. The channel trench CH_T may expose the bit line BL.

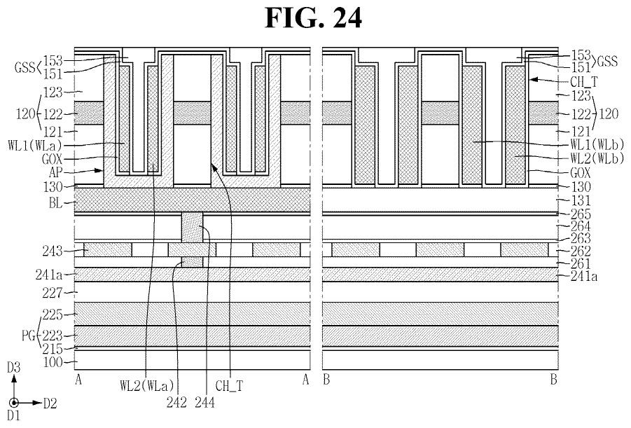

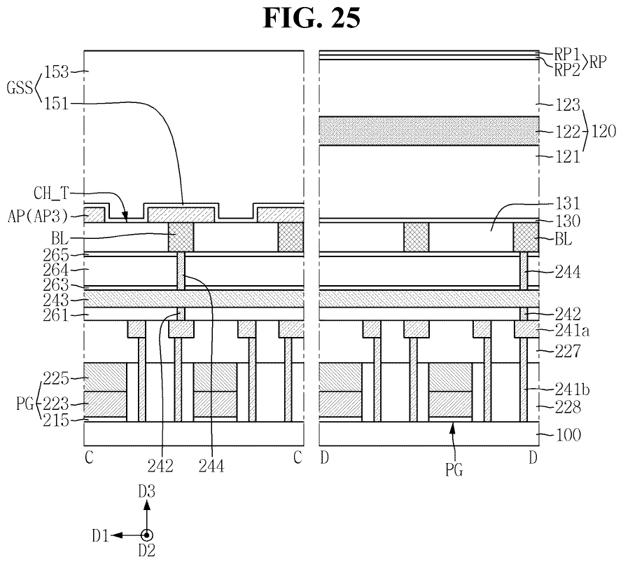

Referring to FIGS. 24 and 25, the oxide pattern structure AP may be formed in the channel trench CH_T. Subsequently, the gate insulating film GOX may be formed on the oxide pattern structure AP. The gate insulating film GOX may be formed along the upper surfaces of the oxide pattern structure AP and the mold insulating structure film 120. In a portion in which the oxide pattern structure AP is not formed, the gate insulating film GOX may be formed along the side walls and the upper surface of the mold insulating structure film 120. The gate insulating film GOX may be formed, but not limited to, using at least one of physical vapor deposition (PVD), thermal chemical vapor deposition (thermal CVD), low pressure chemical vapor deposition (LP-CVD), plasma enhanced chemical vapor deposition (PE-CVD) or atomic layer deposition (ALD) techniques.

Subsequently, a first word line WL1 and a second word line WL2 may be formed on the gate insulating film GOX. The first word line WL1 and the second word line WL2 may be formed along the side walls of the channel trench CH_T. Formation of the first word line WL1 and the second word line WL2 may include performance of an anisotropic etching process on a gate conductive film after depositing the gate conductive film on the gate insulating film GOX.

At the time of the anisotropic etching process on the gate conductive film, a part of the gate insulating film GOX may be etched. Accordingly, the gate insulating film GOX between the first word line WL1 and the oxide pattern structure AP may be separated from the gate insulating film GOX between the second word line WL2 and the oxide pattern structure AP. Unlike the shown example, the gate insulating film GOX may be used as an etching stop film at the time of the anisotropic etching process on the gate conductive film.

The gate separation pattern GSS may be formed on the first word line WL1 and the second word line WL2. The gate separation pattern GSS may fill the channel trench CH_T. More specifically, the gate separation liner 151 may be formed along the profile of the first word line WL1 and the profile of the second word line WL2. The gate separation liner 151 may also be formed on the upper surface of the gate insulating film GOX.

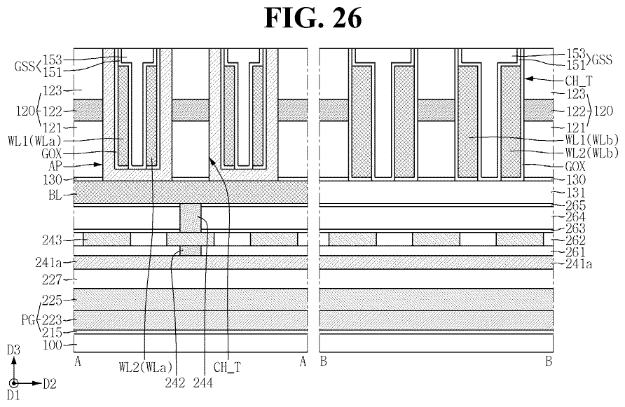

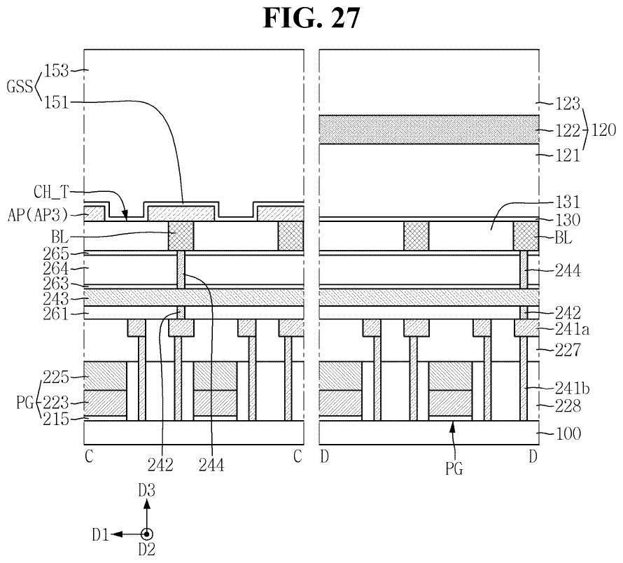

Referring to FIGS. 26 and 27, the gate separation liner 151, the gate insulating film GOX, and the gate separation filling film 153 may be removed through an etching process. Specifically, the gate separation liner 151 formed on the upper surface of the oxide pattern structure AP and the mold insulating structure film 120, the gate insulating film GOX, and the gate separation filling film 153 disposed at the same level may be removed.

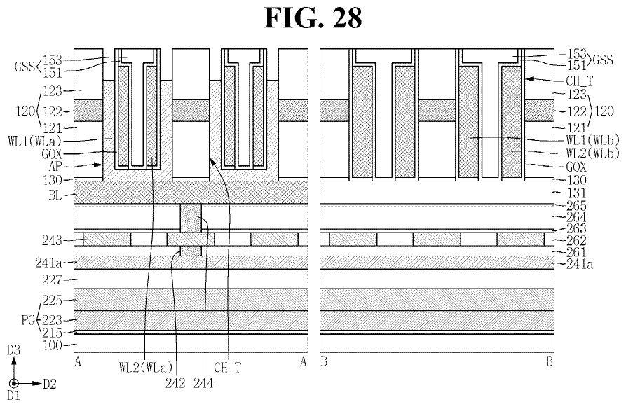

Referring to FIG. 28, the oxide pattern structure AP may be removed through an etching process. At this time, the etching process of the oxide pattern structure AP may be omitted depending on the selectivity of the constituent materials of the oxide pattern structure AP and the third mold insulating film 123 of the mold insulating structure film 120, and the embodiment is not limited thereto.

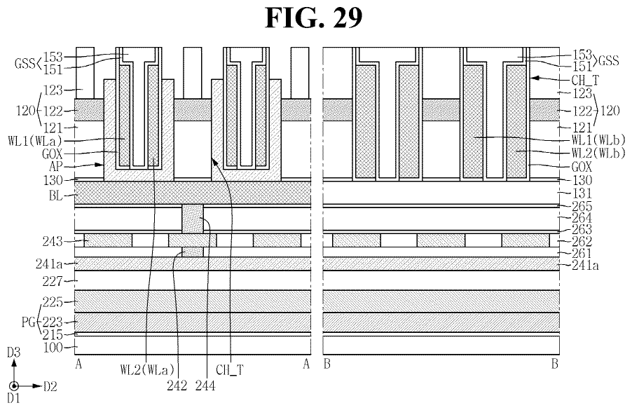

Referring to FIG. 29, the third mold insulating film 123 may be removed through an etching process. A part of the upper surface of the second mold insulating film 122 may be exposed in the third direction. A part of the side wall of the oxide pattern structure AP may be exposed in the second direction. Next, referring to FIGS. 2 and 3, a pre-landing pad film may be formed on the mold insulating structure film 120, the gate separation pattern GSS, and the oxide pattern structure AP. The pre-landing pad film is patterned, and the landing pads LP may also be formed on the oxide pattern structure AP. The data storage pattern DSP may then be formed on the landing pad LP. The data storage pattern DSP is connected to the oxide pattern structure AP and may be formed on the gate separation pattern GSS.

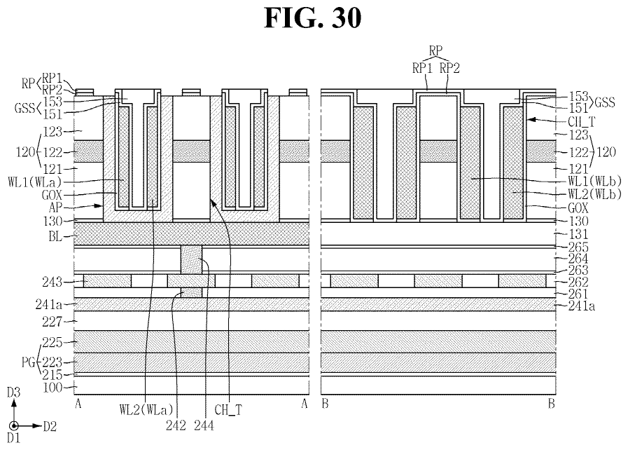

FIGS. 30 to 32 are intermediate stage diagrams for explaining a method for fabricating an integrated circuit memory device according to some embodiments. For convenience of explanation, points different from those explained using FIGS. 20 to 29 will be mainly explained. For reference, the fabricating method described using FIG. 30 may be a fabricating process performed after the process steps shown in FIG. 24.

Referring to FIG. 30, a part of the gate separation liner 151 and the gate insulating film GOX may be removed through the etching process. Specifically, the gate separation liner 151 and the gate insulating film GOX formed on the upper surfaces of the oxide pattern structure AP and the mold insulating structure film 120 may be removed. As a result, in a cross-sectional view taken along the line A-A, the residual insulating pattern RP may not be connected to the gate separation liner 151 and the gate insulating film GOX.

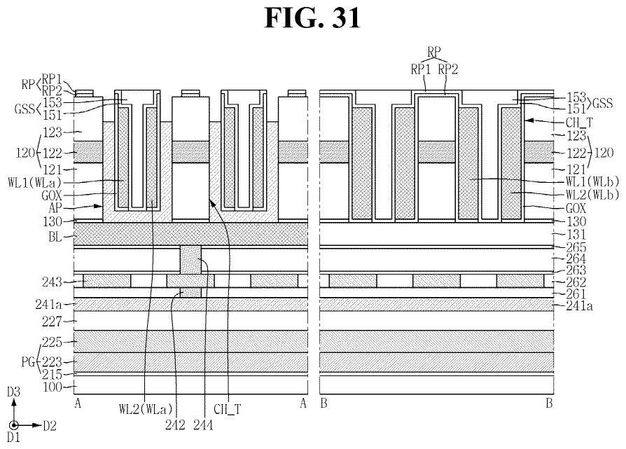

Referring to FIG. 31, the oxide pattern structure AP may be removed through the etching process. At this time, the etching process of the oxide pattern structure AP may be omitted depending on the selectivity of the constituent materials of the oxide pattern structure AP and the third mold insulating film 123 of the mold insulating structure film 120, and the embodiment is not limited thereto.

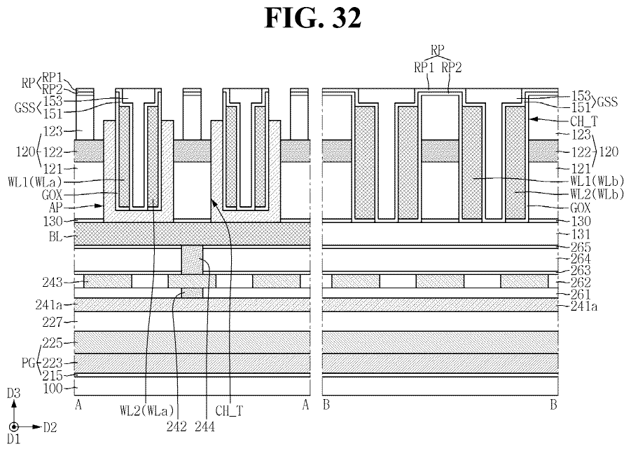

Referring to FIG. 32, the third mold insulating film 123 may be removed through an etching process. A part of the upper surface of the second mold insulating film 122 may be exposed in the third direction. A part of the side wall of the oxide pattern structure AP may be exposed in the second direction.

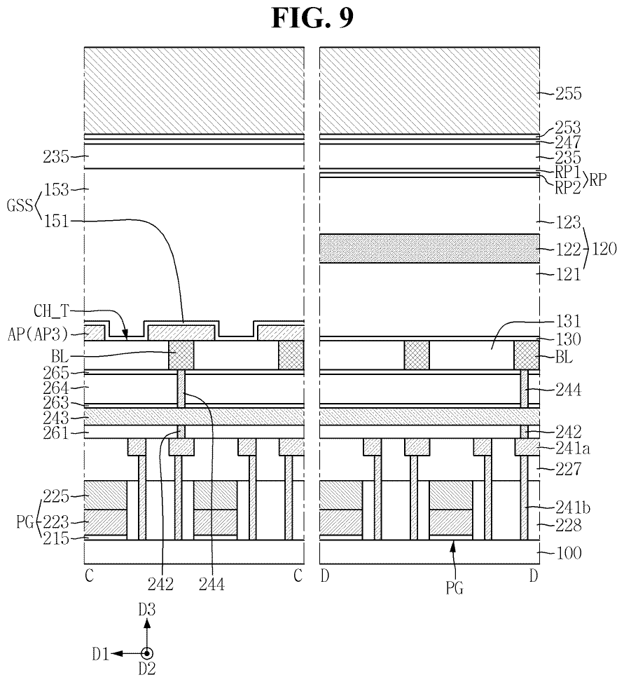

Next, referring to FIGS. 8 and 9, the pre-landing pad film may be formed on the mold insulating structure film 120, the gate separation pattern GSS, and the oxide pattern structure AP. The pre-landing pad film may be patterned to form the landing pads LP on the oxide pattern structure AP. The data storage pattern DSP may then be formed on the landing pad LP. The data storage pattern DSP is connected to the oxide pattern structure AP and may be formed on the gate separation pattern GSS.

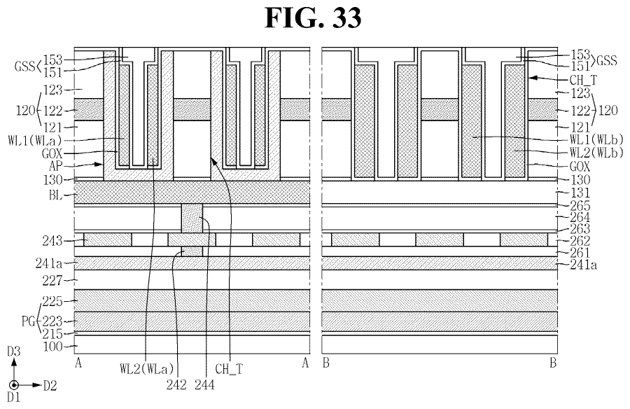

FIGS. 33 to 37 are intermediate stage diagrams for explaining a method for fabricating an integrated circuit memory device according to some embodiments. For convenience of explanation, points different from those explained using FIGS. 20 to 29 will be mainly explained. For reference, the fabricating method described using FIG. 33 may be a fabricating process performed subsequent to the process steps illustrated by FIG. 24.

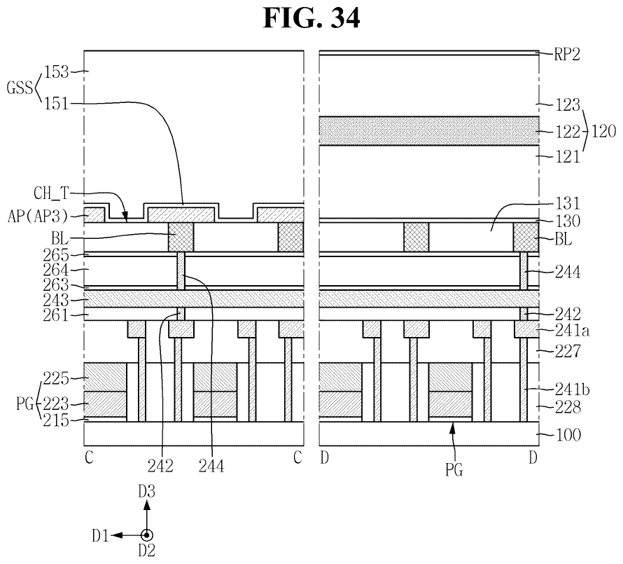

Referring to FIGS. 33 and 34, a part of the gate separation liner 151 and the gate separation filling film 153 may be removed through the etching process. Specifically, the gate separation liner 151 formed on the gate insulating film GOX and the gate separation filling film 153 disposed at the same level may be removed.

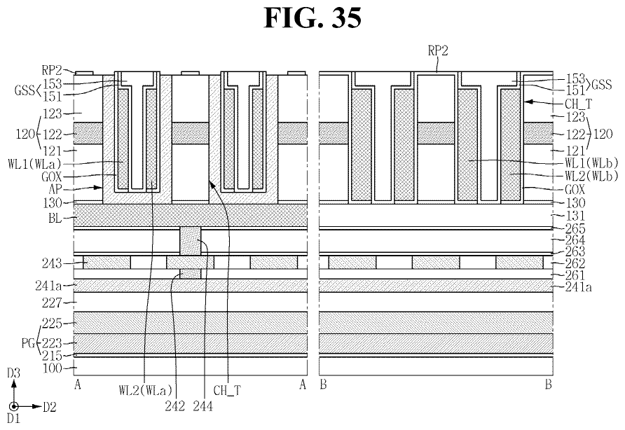

Referring to FIG. 35, a part of the gate insulating film GOX may be removed through the etching process. Specifically, the gate insulating film GOX formed on the upper surfaces of the oxide pattern structure AP and the mold insulating structure film 120 may be removed. Accordingly, the second residual insulating pattern RP2 may not be connected to the gate insulating film GOX in the cross-sectional view taken along the line A-A.

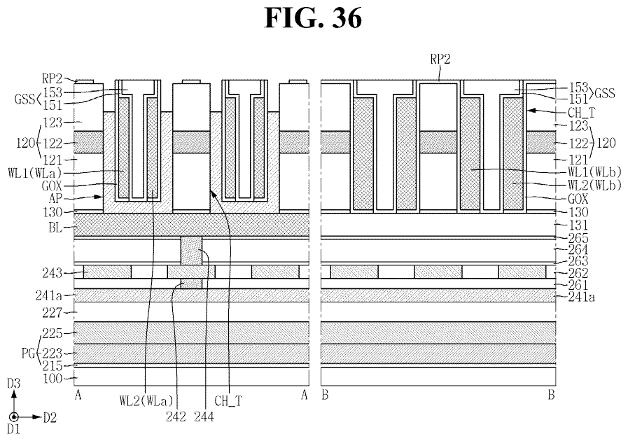

Referring to FIG. 36, the oxide pattern structure AP may be removed through the etching process. At this time, the etching process of the oxide pattern structure AP may be omitted depending on the selectivity of the constituent materials of the oxide pattern structure AP and the third mold insulating film 123 of the mold insulating structure film 120, but the embodiment is not limited thereto.

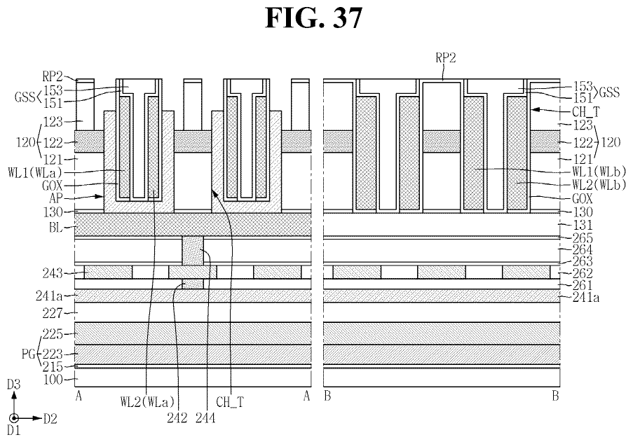

Referring to FIG. 37, the third mold insulating film 123 may be removed through the etching process. A part of the upper surface of the second mold insulating film 122 may be exposed in the third direction. A part of the side wall of the oxide pattern structure AP may be exposed in the second direction.

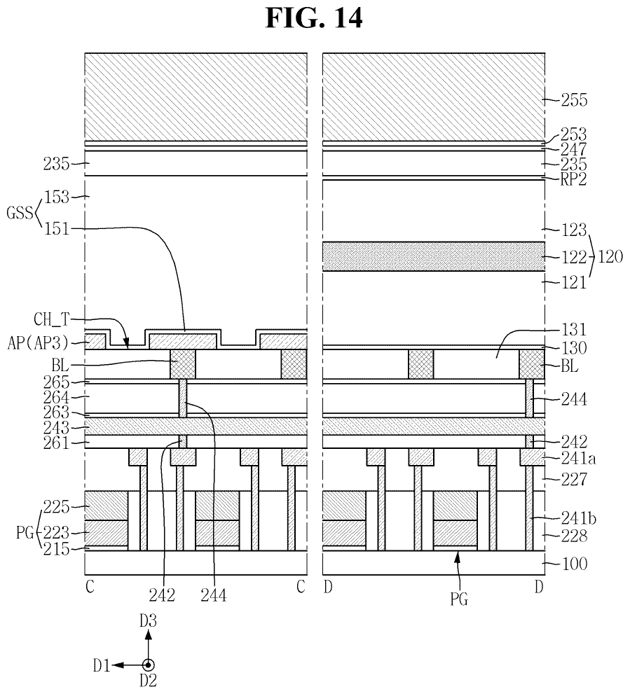

Next, referring to FIGS. 13 and 14, the pre-landing pad film may be formed on the mold insulating structure film 120, the gate separation pattern GSS, and the oxide pattern structure AP. The pre-landing pad film may be patterned to form the landing pads LP on the oxide pattern structure AP.

The data storage pattern DSP may then be formed on the landing pad LP. The data storage pattern DSP is connected to the oxide pattern structure AP, and may be formed on the gate separation pattern GSS.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. An integrated circuit memory device, comprising:
a bit line extending in a first direction across an underlying substrate;
an etching stop film on the bit line;
a mold insulating structure film, which extends on the etching stop film and includes a channel trench extending in a second direction, said mold insulating structure film including a first mold insulating film on the etching stop film, and a second mold insulating film on the first mold insulating film;
a metal oxide pattern extending on the bit line, and along a side wall of the channel trench;
a word line extending on the metal oxide pattern, and in the second direction; and
a data storage pattern extending on the metal oxide pattern, and connected to the metal oxide pattern;
wherein the second mold insulating film includes an upper surface and a bottom surface, which extend opposite to each other in a third direction;
wherein the bottom surface of the second mold insulating film faces the bit line; and
wherein a height from an upper surface of the bit line to an uppermost part of the metal oxide pattern is greater than a height from the upper surface of the bit line to the upper surface of the second mold insulating film.

2. The device of claim 1, wherein the first mold insulating film and the second mold insulating film comprise different materials.

3. The device of claim 2, wherein the first mold insulating film includes silicon oxide, and the second mold insulating film includes silicon nitride.

4. The device of claim 2, wherein the mold insulating structure film further includes a third mold insulating film on the second mold insulating film.

5. The device of claim 4, wherein the first and third mold insulating films comprise the same material.

6. The device of claim 1, further comprising:
a landing pad extending between the metal oxide pattern and the data storage pattern, and contacting the second mold insulating film.

7. The device of claim 6, wherein a height from the upper surface of the bit line to a lowermost part of the landing pad is identical to the height from the upper surface of the bit line to the upper surface of the second mold insulating film.

8. The device of claim 6, wherein the height from the upper surface of the bit line to the uppermost part of the metal oxide pattern is greater than the height from the upper surface of the bit line to the lowermost part of the landing pad.

9. The device of claim 1, wherein the height from the upper surface of the bit line to the uppermost part of the metal oxide pattern is smaller than the height from the upper surface of the bit line to the uppermost part of the word line.

10. The device of claim 1, wherein the metal oxide pattern includes a material selected from a group consisting of: IGZO, impurity-doped IZO, InO, ZnO, GaO, SnO, AZO, and ITO.

11. An integrated circuit memory device, comprising:
a bit line extending in a first direction on a substrate;
an etching stop film on the bit line;
a mold insulating structure film, which extends on the etching stop film and includes a channel trench extending in a second direction;
a metal oxide pattern extending on the bit line, and along a side wall of the channel trench;
a word line extending on the metal oxide pattern, and in the second direction; and
a data storage pattern, which extends on the metal oxide pattern, and is connected to the metal oxide pattern;
wherein the mold insulating structure film includes a first mold insulating film, a second mold insulating film, and a third mold insulating film that are sequentially stacked on the etching stop film, such that the second mold insulating film extends between the first mold insulating film and the third mold insulating film;
wherein the second mold insulating film includes an upper surface and a bottom surface, which extend opposite to each other in a third direction;
wherein the bottom surface of the second mold insulating film faces the bit line; and
wherein a height from an upper surface of the bit line to an uppermost part of the metal oxide pattern is greater than a height from the upper surface of the bit line to the bottom surface of the second mold insulating film.

12. The device of claim 11, wherein the height from the upper surface of the bit line to the uppermost part of the metal oxide pattern is greater than or equal to a height from the upper surface of the bit line to the upper surface of the second mold insulating film.

13. The device of claim 11, wherein the first and third mold insulating films comprise the same material, and the first mold insulating film includes a material different from the second mold insulating film.

14. The device of claim 13, wherein the first mold insulating film includes silicon oxide, and the second mold insulating film includes silicon nitride.

15. The device of claim 11, further comprising:
a gate insulating film extending between the metal oxide pattern and the word line; and
a residual insulating pattern extending on the mold insulating structure film, said residual insulating pattern including the same material as the gate insulating film.

16. The device of claim 11, further comprising:
a landing pad extending between the metal oxide pattern and the data storage pattern, and contacting the upper surface of the second mold insulating film.

17. The device of claim 16, wherein the height from the upper surface of the bit line to the uppermost part of the metal oxide pattern is greater than the height from the upper surface of the bit line to the lowermost part of the landing pad.

18. An integrated circuit memory device, comprising:
a bit line extending in a first direction across an underlying substrate;
a first metal oxide pattern and a second metal oxide pattern, which extend on the bit line and are spaced apart from each other in the first direction;
a mold insulating structure film extending on the bit line, and between the first and second metal oxide patterns;
a first word line extending on the first metal oxide pattern, and in a second direction;
a second word line extending on the second metal oxide pattern, and in the second direction; and
a data storage pattern extending on and connected to the first and second metal oxide patterns;
wherein the mold insulating structure film includes a first mold insulating film, a second mold insulating film, and a third mold insulating film that are sequentially stacked on the bit line;
wherein the second mold insulating film extends between the first mold insulating film and the third mold insulating film;
wherein the second mold insulating film and the third mold insulating film each include an upper surface and a bottom surface that extend opposite to each other in a third direction;
wherein the upper surface of the second mold insulating film faces the bottom surface of the third mold insulating film; and
wherein a width of the upper surface of the second mold insulating film in the first direction is greater than a width of the bottom surface of the third mold insulating film in the first direction.

19. The device of claim 18, wherein a height from the upper surface of the bit line to an uppermost part of the first metal oxide pattern is greater than or equal to a height from the upper surface of the bit line to the upper surface of the second mold insulating film.

20. The device of claim 18, further comprising:
a landing pad extending between the first metal oxide pattern and the data storage pattern, and contacting the upper surface of the second mold insulating film and a side wall of the third mold insulating film.
